(19) United States
(12) Patent Application Publication
(10) Pub. No.: US 2026/0173917 A1
(43) Pub. Date: Jun. 18, 2026

(54) PACKAGE STRUCTURE AND METHOD FOR FORMING THE SAME

(71) Applicant: JCET Microelectronics (Jiangyin) Co., LTD., Jiangyin (CN)

(72) Inventors: Qingyun ZHOU, Jiangyin (CN); Ming SHENG, Jiangyin (CN); Jiayu DONG, Jiangyin (CN); Cong YI, Jiangyin (CN); Hengyang ZHANG, Jiangyin (CN)

(73) Assignee: JCET Microelectronics (Jiangyin) Co., LTD., Jiangyin (CN)

(21) Appl. No.: 19/416,989

(22) Filed: Dec. 11, 2025

(30) Foreign Application Priority Data
Dec. 12, 2024 (CN) 202411828821.4

(51) Int. Cl. H10W 70/60; H10W 70/05; H10W 70/63; H10W 70/65

(52) U.S. Cl. CPC H10W 70/616; H10W 70/095; H10W 70/635; H10W 70/65

(57) ABSTRACT

The present disclosure provides a package structure and a method for forming the same. Conductive pillars are not arranged on the top of the internal redistribution layer of the bridge chip, which reduces the overall thickness of the bridge chip, thus reducing defects caused by excessive thickness of the bridge chip during the manufacturing process, and reducing the thickness of the wiring interposer composed of the first molding layer and the bridge chip component, thereby reducing warping issues and quality risks of each process during the overall manufacturing process.

### CROSS-REFERENCE TO RELATED APPLICATIONS

This application claims the benefit of priority to Chinese Application No. 202411828821.4, filed Dec. 12, 2024, which is incorporated herein by reference in its entirety.

### TECHNICAL FIELD

The present disclosure relates to the field of semiconductor package, and particularly relates to a package structure and a method for forming the same.

### BACKGROUND

Advanced package is a novel electronic package technology, which is intended to integrate a plurality of chips or other electronic components together, with higher integration level, smaller size, lower power consumption, and higher reliability through innovative technical approaches.

In Wafer Level Package (WLP), most of its package processes are performed on the wafer, and the demand for wafer level package is not only subject to requirements for smaller package dimensions and height but also needs to meet the requirements of simplifying the supply chain, reducing overall costs, and improving overall performance.

### SUMMARY

Embodiments of the present disclosure provide a method for forming a package structure, which includes: forming a bridge chip component, the bridge chip component includes: a bridge chip, a protective layer, an adhesive layer, and a film layer; the bridge chip includes a base body, through-silicon-vias running through the base body, and an internal redistribution layer covering the top surface of the base body, and the internal redistribution layer is electrically connected with the through-silicon-vias; the protective layer is arranged on the bottom surface of the base body and exposes the bottom surfaces of the through-silicon-vias, wherein the bottom surfaces of the through-silicon-vias are made flush with the bottom surface of the protective layer by the manner of depositing the protective layer first and then thinning the through-silicon-vias; the adhesive layer covers the bottom surface of the protective layer and the bottom surfaces of the through-silicon-vias; the film layer covers the top surface of the internal redistribution layer; arranging the bridge chip component on the top surface of a carrier board in a flip-chip or a face-up chip manner; performing molding using a film assistant molding process to form a first molding layer, which covers the side surface of the bridge chip component and the top surface of the carrier board, and the adhesive layer or the film layer is exposed on the first molding layer; removing the exposed adhesive layer or the film layer; removing a part of the first molding layer, such that the surface of the first molding layer facing away from the carrier board is flush with the surface of the bridge chip component facing away from the carrier board; forming a chip package component on the surface of the first molding layer facing away from the carrier board and on the surface of the bridge chip component facing away from the carrier board, and the bridge chip component is electrically connected with the chip package component; removing the carrier board and the adhesive layer or the film layer of the bridge chip component, and removing a part of the first molding layer, such that the surface of the first molding layer facing away from the chip package component is flush with the surface of the bridge chip component facing away from the chip package component; and forming a bottom interconnection structure on the surface of the first molding layer facing away from the chip package component and on the surface of the bridge chip component facing away from the chip package component.

Embodiments of the present disclosure further provide a package structure, which includes: a bridge chip component, the bridge chip component including a bridge chip and a protective layer; the bridge chip includes a base body, through-silicon-vias running through the base body, and an internal redistribution layer covering the top surface of the base body, and the protective layer is arranged on the bottom surface of the base body and exposes the bottom surfaces of the through-silicon-vias, and the bottom surfaces of the through-silicon-vias are flush with the bottom surface of the protective layer; a first molding layer, the first molding layer covering the side surface of the bridge chip component, and the bottom surface of the first molding layer is flush with the bottom surface of the protective layer, and the top surface of the first molding layer is flush with the top surface of the internal redistribution layer; a chip package component arranged on a surface of the first molding layer and the bridge chip component, and the bridge chip component is electrically connected with the chip package component; and a bottom interconnection structure arranged on another surface of the first molding layer and the bridge chip component, and the bridge chip component is electrically connected with the bottom interconnection structure; wherein the internal redistribution layer is directly electrically connected with the chip package component or the bottom interconnection structure.

The conductive pillars are not arranged on the top of the internal redistribution layer of the bridge chip, which reduces the overall thickness of the bridge chip, thus reducing defects caused by excessive thickness of the bridge chip during the manufacturing process. For example, it reduces the covering thickness during molding of the bridge chip, and it reduces the thickness of the wiring interposer composed of the first molding layer and the bridge chip component, thereby reducing warping issues and quality risks of each process during the overall manufacturing process. In the formation method, a film layer is arranged on the top of the bridge chip component, and an adhesive layer is arranged on the bottom of the bridge chip component, which is conducive to the embedding of ultra-thin bridge chips.

In the formation method, the bridge chip component is first formed, wherein the through-silicon-vias of the bridge chip are exposed by the manner of depositing a protective layer first and then thinning the through-silicon-vias, so that the protective layer can protect the base body during the thinning process, which may avoid the migration and diffusion of metal ions (e.g., copper ions) generated by thinning the through-silicon-vias into the base body, thereby avoiding the reliability failure problems caused by the migration and diffusion of metal ions in the package structure.

In the formation method, the first molding layer is directly formed using the film assistant molding (FAM) process, without the need to first form a thicker pre-molding layer and then thin it to form the first molding layer, which avoids warping caused by excessive thickness of pre-molding layers during manufacturing process, thereby avoiding warping affecting the process operation; moreover, by directly forming the first molding layer, it facilitates reduction of the heights of other components (e.g., the heights of metal pillars), which can shorten their spacing and critical dimensions, and thus form a higher connection density, which is conducive to the miniaturization of the product.

In the package structure formed by the formation method, the bridge chip is directly connected with the chip package component or the bottom interconnection structure through the internal redistribution layer fan-out, without the need to fan out through the internal redistribution layer and then connect it with the chip package component or the bottom interconnection structure through conductive pillars, which better meets the product application requirements of high-frequency and high-speed signals. The top surface of the first molding layer is flush with the top surface of the internal redistribution layer, and the bottom surface of the first molding layer is flush with the bottom surface of the bridge chip component, i.e., the upper and lower surfaces of the bridge chip component are of the same height as the surface of the first molding layer, which can further improve the interconnection density between the bridge chip and the chip package component on the top (e.g., the top redistribution layer in the chip package component) as well as the bottom interconnection structure (e.g., the bottom redistribution layer in the bottom interconnection structure).

### BRIEF DESCRIPTION OF THE DRAWINGS

In order to more clearly explain the technical solutions in the embodiments of the present disclosure, the accompanying drawings necessary for the description of the embodiments will be briefly introduced below. It is obvious that the accompanying drawings described below are only some embodiments of the present disclosure, and for those skilled in the art, other accompanying drawings can also be obtained according to these accompanying drawings without inventive effort.

FIG. 1 is a schematic diagram of the steps of a method for forming a package structure provided by an embodiment of the present disclosure;

FIGS. 2 to 17 are process flow schematic diagrams of a method for forming a package structure provided by an embodiment of the present disclosure; and

FIG. 18 is a schematic diagram of the package structure formed by a formation method provided by another embodiment of the present disclosure.

### DETAILED DESCRIPTION OF EMBODIMENTS

The specific implementation of the package structure and the method for forming the same provided by the present disclosure will be described in detail below with reference to the accompanying drawings.

Fan-out wafer level package can be categorized into Die First and Die Last processes according to process flow; Die First process simply means the chip is placed first, and then a wiring (redistribution layer, RDL) is formed, and Die Last means a wiring is formed first, then the chip is placed onto the units that pass the test. In advanced package structure using Die Last, a bridge chip (Si Bridge Die) needs to be embedded in the wiring interposer (interposer), and this bridge chip is a structure having TSV and DTC functionality. Wherein one surface of the bridge chip needs to be connected with the corresponding redistribution layer through conductive pillars (Stud), and another surface needs to be connected with the corresponding redistribution layer through bumps, while the addition of the thickness of the bridge chip, the thickness of the conductive pillars, and the thickness of the bumps makes the thickness of the initial pre-molding structure and the thickness of the final formed wiring interposer be thicker, resulting in larger warping and affecting the process operation.

Therefore, how to reduce the thickness of the wiring interposer and thus to decrease the problem of warping has become a key focus of current research.

The technical problem to be solved by the present disclosure is to provide a package structure and a method for forming the same, which can reduce the thickness of the wiring interposer, thereby reducing warping issues and quality risks of each process during the overall manufacturing process.

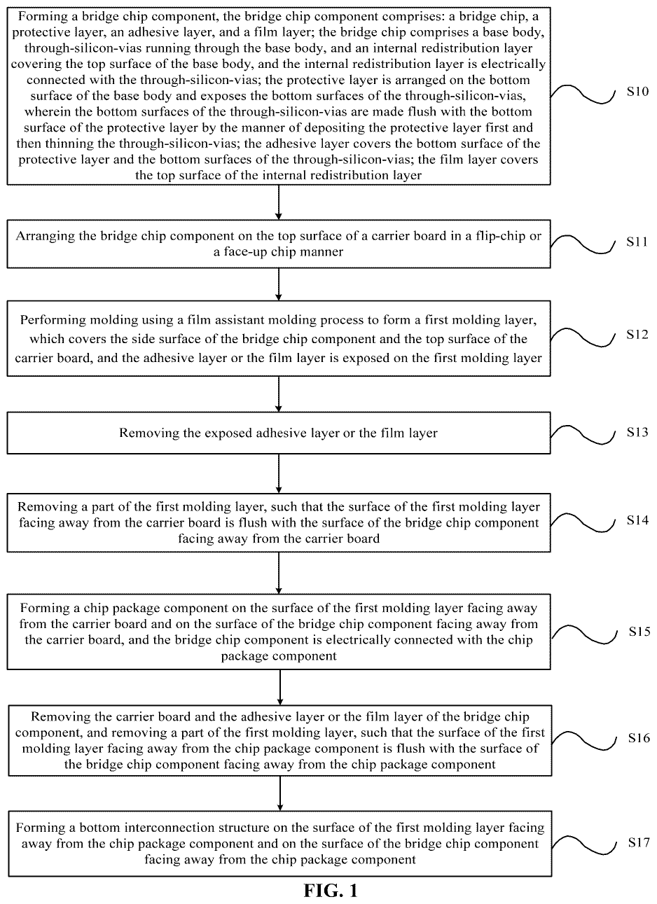

FIG. 1 is a schematic diagram of the steps of a method for forming a package structure provided by an embodiment of the present disclosure, referring to FIG. 1, the forming method includes: step S10, forming a bridge chip component, the bridge chip component includes: a bridge chip, a protective layer, an adhesive layer, and a film layer; the bridge chip includes a base body, through-silicon-vias running through the base body, and an internal redistribution layer covering the top surface of the base body, and the internal redistribution layer is electrically connected with the through-silicon-vias; the protective layer is arranged on the bottom surface of the base body and exposes the bottom surfaces of the through-silicon-vias, wherein the bottom surfaces of the through-silicon-vias are made flush with the bottom surface of the protective layer by the manner of depositing the protective layer first and then thinning the through-silicon-vias; the adhesive layer covers the bottom surface of the protective layer and the bottom surfaces of the through-silicon-vias; the film layer covers the top surface of the internal redistribution layer; step S11, arranging the bridge chip component on the top surface of a carrier board in a flip-chip or a face-up chip manner; step S12, performing molding using a film assistant molding process to form a first molding layer, which covers the side surface of the bridge chip component and the top surface of the carrier board, and the adhesive layer or the film layer is exposed on the first molding layer; step S13, removing the exposed adhesive layer or the film layer; step S14, removing a part of the first molding layer, such that the surface of the first molding layer facing away from the carrier board is flush with the surface of the bridge chip component facing away from the carrier board; step S15, forming a chip package component on the surface of the first molding layer facing away from the carrier board and on the surface of the bridge chip component facing away from the carrier board, and the bridge chip component is electrically connected with the chip package component; step S16, removing the carrier board and the adhesive layer or the film layer of the bridge chip component, and removing a part of the first molding layer, such that the surface of the first molding layer facing away from the chip package component is flush with the surface of the bridge chip component facing away from the chip package component; and step S17, forming a bottom interconnection structure on the surface of the first molding layer facing away from the chip package component and on the surface of the bridge chip component facing away from the chip package component.

The conductive pillars are not arranged on the top of the internal redistribution layer of the bridge chip, which reduces the overall thickness of the bridge chip, thus reducing defects caused by excessive thickness of the bridge chip during the manufacturing process, for example, it reduces the covering thickness during molding of the bridge chip, and it reduces the thickness of the wiring interposer composed of the first molding layer and the bridge chip component, thereby reducing warping issues and quality risks of each process during the overall manufacturing process. In the formation method, a film layer is arranged on the top of the bridge chip component, and an adhesive layer is arranged on the bottom of the bridge chip component, which is conducive to the embedding of ultra-thin bridge chips.

In the formation method, the bridge chip component is first formed, wherein the through-silicon-vias of the bridge chip are exposed by the manner of depositing a protective layer first and then thinning the through-silicon-vias, so that the protective layer can protect the base body during the thinning process, which may avoid the migration and diffusion of metal ions (e.g., copper ions) generated by thinning the through-silicon-vias into the base body, thereby avoiding the reliability failure problems caused by the migration and diffusion of metal ions in the package structure.

In the formation method, the first molding layer is directly formed using the film assistant molding (FAM) process, without the need to first form a thicker pre-molding layer and then thin it to form the first molding layer, which avoids warping caused by excessive thickness of pre-molding layers during manufacturing process, thereby avoiding warping affecting the process operation; moreover, by directly forming the first molding layer, it facilitates reduction of the heights of other components (e.g., the heights of metal pillars), which can shorten their spacing and critical dimensions, and thus form a higher connection density, which is conducive to the miniaturization of the product.

In the package structure formed by the formation method, the bridge chip is directly connected with the chip package component or the bottom interconnection structure through the internal redistribution layer fan-out, without the need to fan out through the internal redistribution layer and then connect it with the chip package component or the bottom interconnection structure through conductive pillars, which better meets the product application requirements of high-frequency and high-speed signals. The top surface of the first molding layer is flush with the top surface of the internal redistribution layer, and the bottom surface of the first molding layer is flush with the bottom surface of the bridge chip component, i.e., the upper and lower surfaces of the bridge chip component are of the same height as the first molding layer, which can further improve the interconnection density between the bridge chip and the chip package component on the top (e.g., the top redistribution layer in the chip package component) as well as the bottom interconnection structure (e.g., the bottom redistribution layer in the bottom interconnection structure).

FIGS. 2 to 17 are process flow schematic diagrams of a method for forming a package structure provided by an embodiment of the present disclosure.

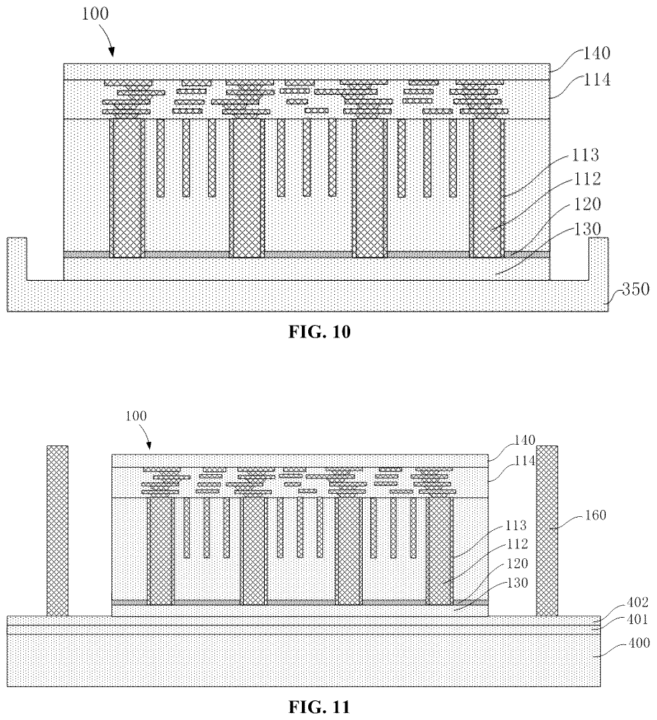

Referring to FIGS. 1 and 10, at step S10, a bridge chip component 100 is formed, the bridge chip component 100 includes: a bridge chip 110, a protective layer 120, an adhesive layer 130, and a film layer 140; the bridge chip 110 includes a base body 111, through-silicon-vias 112 running through the base body 111, and an internal redistribution layer 114 covering the top surface of the base body 111, and the internal redistribution layer 114 is electrically connected with the through-silicon-vias 112; the protective layer 120 is arranged on the bottom surface of the base body 111 and exposes the bottom surfaces of the through-silicon-vias 112, wherein the bottom surfaces of the through-silicon-vias 112 are made flush with the bottom surface of the protective layer 120 by the manner of depositing the protective layer 120 first and then thinning the through-silicon-vias 112; the adhesive layer 130 covers the bottom surface of the protective layer 120 and the bottom surfaces of the through-silicon-vias 112; the film layer 140 covers the top surface of the internal redistribution layer 114.

In the bridge chip component 100 provided by the embodiments of the present disclosure, the bottom surfaces of the through-silicon-vias 112 are flush with the bottom surface of the protective layer 120, and when manufacturing the bridge chip component 100, the protective layer 120 is first deposited, and then the bottom surfaces of the through-silicon-vias 112 are ground, the protective layer 120 can protect the base body 111 during the grinding process, which may avoid the migration and diffusion of metal ions (e.g., copper ions) generated by grinding the through-silicon-vias 112 into the base body 111, thereby avoiding the reliability failure problems caused by the migration and diffusion of metal ions in the package structure.

In one embodiment, the base body 111 is a silicon base body, the through-silicon-vias 112 are copper pillars, and the internal redistribution layer 114 covers on the top surface of the silicon base body and is electrically connected with the top surfaces of the through-silicon-vias 112, the internal redistribution layer 114 includes a dielectric layer and conductive lines located within the dielectric layer, one side of the conductive lines is electrically connected with the top surfaces of the through-silicon-vias 112, and the other side is used to be electrically connected with the chip package component 170 or the bottom interconnection structure 180. The dielectric layer may be a silicon dioxide layer or a silicon nitride layer, and etc. In one embodiment, a passivation layer 113 is further arranged on the side surfaces of the through-silicon-vias 112 (labeled in FIG. 2), the passivation layer 113 is used to isolate the through-silicon-vias 112 from the base body 111 to prevent metal ions in the through-silicon-vias 112 from diffusing into the base body 111, the passivation layer 113 includes, but is not limited to silicon oxide, silicon nitride, and combinations thereof.

In one embodiment, the protective layer 120 is a single-layer or a composite-layer structure, its materials including but not limited to silicon nitride, silicon dioxide, or nitride-silicon dioxide. The adhesive layer 130 is composed of a material with a certain adhesiveness, such as acrylic resin series. In some embodiments, the adhesive layer 130 is a die attachment film (DAF), which has excellent thermal conductivity and adhesiveness. The film layer 140 is composed of a material which has a certain adhesiveness and which can be removed, such as a UV-curable PI film, which has good adhesiveness and which can be removed through UV irradiation or wet etching method.

The present disclosure further provides a method for forming a bridge chip component 100; specifically, the steps of forming the bridge chip component 100 include:

Referring to FIG. 2, a device wafer is provided, and the device wafer includes a bridge chip 110, and the bridge chip 110 includes an initial base body 200, initial through-silicon-vias 210 extending from the top surface of the initial base body 200 toward the interior of the initial base body 200, and an internal redistribution layer 114 arranged on the top surface of the initial base body 200, a passivation layer 113 is covered on the sidewalls and bottom surfaces of the initial through-silicon-vias 210, and the top surfaces of the initial through-silicon-vias 210 contact the bottom surface of the internal redistribution layer 114.

In some embodiments, the bridge chip 110 further includes a deep trench capacitor (DTC) 180, the deep trench capacitor is arranged within the initial base body 200. In some embodiments, the deep trench capacitor 180 extends from the top surface of the initial base body 200 toward the interior of the initial base body 200, and the deep trench capacitor 180 is electrically connected with the bottom surface of the internal redistribution layer 114.

In some embodiments, the step of providing a device wafer specifically includes: providing an initial wafer, the initial wafer includes an initial base body 200, initial through-silicon-vias 210 extending from the top surface of the initial base body 200 toward the interior of the initial base body 200, and a deep trench capacitor 180 extending from the top surface of the initial base body 200 toward the interior of the initial base body 200; and forming an internal redistribution layer 114 on the top surface of the initial base body 200, and the internal redistribution layer 114 is electrically connected with the top surfaces of the initial through-silicon-vias 210. In some embodiments, the top surfaces of the initial through-silicon-vias 210 and the deep trench capacitor 180 are flush with the top surface of the initial base body 200.

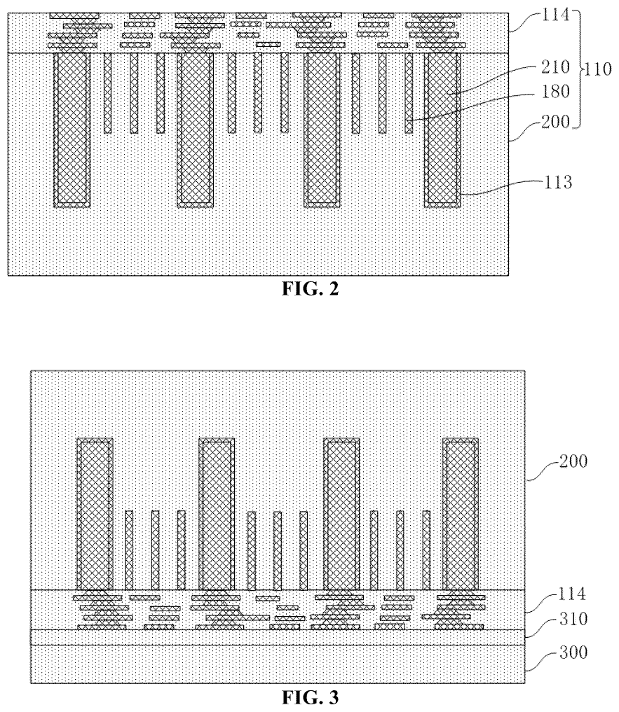

Optionally, in some embodiments, in order for the device wafer to be supported in the subsequent step of processing the bottom surface of the device wafer (e.g., thinning the initial base body 200), after the step of providing the device wafer, it further includes: referring to FIG. 3, bonding the support substrate 300 with the front surface of the device wafer. The support substrate 300 includes but is not limited to a glass substrate. Furthermore, the step of bonding the support substrate 300 with the front surface of the device wafer includes: bonding the support substrate 300 with the surface of the device wafer having the internal redistribution layer 114. Specifically, this step includes: forming a bonding layer 310 on the top surface of the internal redistribution layer 114, and in the case of taking the surface of the support substrate 300 and the surface of the bonding layer 310 as the bonding surfaces, bonding the support substrate 300 with the device wafer.

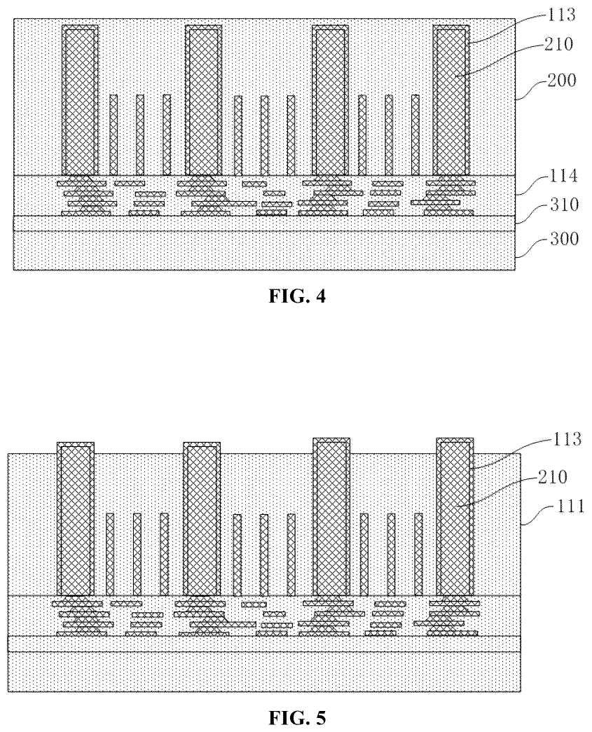

Referring to FIGS. 4 and 5, a part of the initial base body 200 is removed from the bottom surface of the initial base body 200 to form the base body 111, and the initial through-silicon-vias 210 protrude from the bottom surface of the base body 111.

In some embodiments, this step may include the following two steps:

Referring to FIG. 4, a thinning and planarization process is used to remove a part of the initial base body 200 from the bottom surface of the initial base body 200 to a position at a predetermined distance from the passivation layer 113 on the bottom surfaces of the initial through-silicon-vias 210. Specifically, the initial base body 200 is processed using a thinning and planarization process from the bottom surface of the initial base body 200 to a position close to the initial through-silicon-vias 210, and the initial through-silicon-vias 210 are covered by the passivation layer 113, and the passivation layer 113 is covered by the initial base body 200, and the initial through-silicon-vias 210 are still unexposed, which can prevent the initial through-silicon-vias 210 from exposing copper ion to contaminate the base body 111. During the thinning process, the support substrate 300 supports the device wafer. As shown in FIG. 4, in this step, the support substrate 300 is oriented downward, and the device wafer is located above the support substrate 300.

Referring to FIG. 5, a part of the initial base body 200 is removed from the bottom surface of the initial base body 200 using a dry etching process to form the base body 111, and the initial through-silicon-vias 210 protrude from the bottom surface of the base body 111. As shown in FIG. 5, when performing this step, the support substrate 300 is oriented downward, and the device wafer is located above the support substrate 300. In this step, the initial through-silicon-vias 210 are not removed, such that the initial through-silicon-vias 210 protrude from the bottom surface of the base body 111, and the deep trench capacitor 180 is not exposed at the bottom surface of the base body 111. A dry etching process is used to remove a part of the initial base body 200, the dry etching material can etch the initial base body 200 without etching the passivation layer 113 on the surfaces of the initial through-silicon-vias 210, thereby preventing copper ion contamination of the base body 111 and subsequent process chambers.

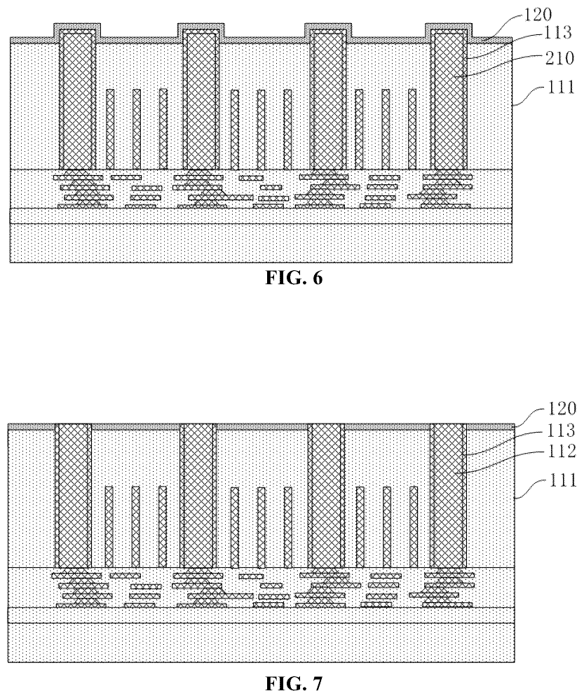

Referring to FIG. 6, a protective layer 120 is formed on the bottom surface of the base body 111. In the present embodiment, the protective layer 120 also covers the surface of the passivation layer 113. In this step, the protective layer 120 may be formed using processes such as chemical vapor deposition (CVD), plasma-enhanced chemical vapor deposition (PECVD), low-pressure chemical vapor deposition (LPCVD), and etc. In other embodiments, the protective layer 120 may cover only the bottom surface of the base body 111.

Referring to FIG. 7, the passivation layer 113 and the initial through-silicon-vias 210 are thinned from the bottom surfaces of the initial through-silicon-vias 210 to form the through-silicon-vias 112, thereby making the bottom surfaces of the through-silicon-vias 112 flush with the bottom surface of the protective layer 120, the passivation layer 113 is covered on the sidewalls of the through-silicon-vias 112. In this step, the protective layer 120 is further covered on the surface of the passivation layer 113, then the protective layer 120 on the top surface of the passivation layer 113, the passivation layer 113, and the initial through-silicon-vias 210 are sequentially thinned, and when the thinning of the initial through-silicon-vias 210 is continued, the passivation layer 113 on the side surfaces of the initial through-silicon-vias 210 and the protective layer 120 covering the surface of the passivation layer 113 are also removed simultaneously. In this step, chemical mechanical polishing (CMP) may be used to grind the initial through-silicon-vias 210 until the formed through-silicon-vias 112 meet a predetermined height requirement. In some embodiments, the bottom surface of the protective layer 120 is simultaneously ground to provide a flat surface for subsequent processes. When grinding the initial through-silicon-vias 210, the surface of the base body 111 is covered by the protective layer 120, and the metal ions generated during grinding cannot diffuse into the base body 111, thereby avoiding the reliability failure problems caused by the migration and diffusion of metal ions in the package structure.

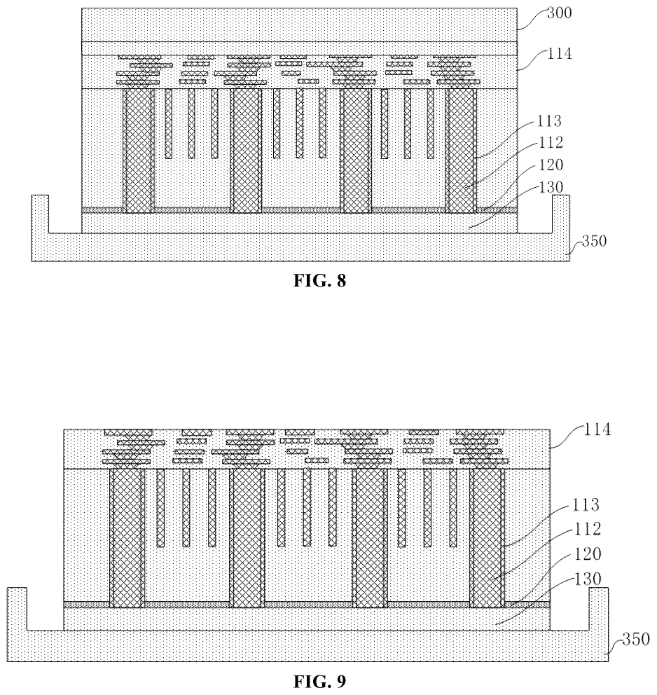

Referring to FIG. 8, an adhesive layer 130 is formed, the adhesive layer 130 covers the bottom surface of the protective layer 120 and the bottom surfaces of the through-silicon-vias 112. The bridge chip component 100 is fixed on the wafer ring 350 through the adhesive layer 130. In some embodiments, the bottom surface of the device wafer is fixed on the wafer ring 350 through the adhesive layer 130, and the support substrate 300 faces upward.

In some embodiments, after the step of forming the adhesive layer 130, it further includes: referring to FIG. 9, the support substrate 300 is debonded. In this step, after the support substrate 300 is debonded, the bonding layer 310 on the front surface of the device wafer is also removed, the internal redistribution layer 114 is exposed. In some embodiments, a suitable debonding process may be selected according to the characteristics of the temporary bonding adhesive, such as laser debonding, thermal debonding, and etc.

Referring to FIG. 10, a film layer 140 is formed. The film layer 140 covers the top surface of the internal redistribution layer 114. In some embodiments, the film layer 140 may be formed through processes such as spin coating and etc., or by covering and pressing a dry film of a certain thickness. After the film layer 140 is formed, the device wafer is diced to form the bridge chip component 100.

The above is one embodiment for forming the bridge chip component 100.

Referring to FIGS. 1 and 11, at step S11, the bridge chip component 100 is arranged on the top surface of a carrier board 400 in a flip-chip or a face-up chip manner. In the present embodiment, in this step, the bridge chip component 100 is arranged on the top surface of the carrier board 400 in a face-up chip manner, and the adhesive layer 130 contacts the top surface of the carrier board 400. In another embodiment, in this step, the bridge chip component 100 is arranged on the top surface of the carrier board 400 in a flip-chip manner, and the film layer 140 contacts the top surface of the carrier board 400.

In some embodiments, the carrier board 400 is a glass base board, whose surface has a temporary bonding layer 401 and a buffer metal layer 402. The bridge chip component 100 is arranged on the buffer metal layer 402 through a die mount or a die attach (DA) process. In some embodiments, in this step, metal pillars 160 are also arranged on the surface of the carrier board 400. The metal pillars 160 may be formed through an electroplating process, which can better meet the product application requirements of high-frequency and high-speed signals.

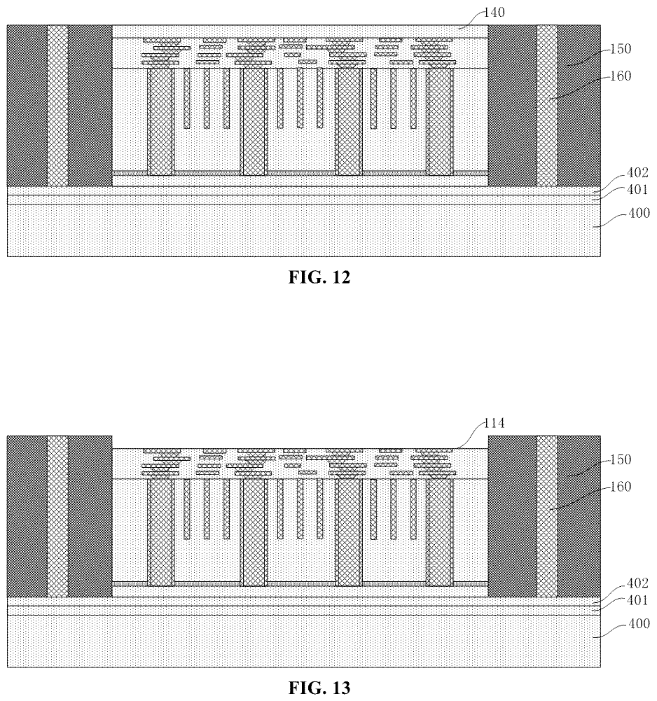

Referring to FIGS. 1 and 12, at step S12, a film assistant molding (FAM) process is used for molding to form a first molding layer 150, the first molding layer 150 covers the side surface of the bridge chip component 100 and the top surface of the carrier board 400, and the adhesive layer 130 or the film layer 140 is exposed on the first molding layer 150. In the present embodiment, the bridge chip component 100 is arranged on the top surface of the carrier board 400 in a face-up chip manner, thus in this step, the film layer 140 is exposed on the first molding layer 150; in another embodiment, the bridge chip component 100 is arranged on the top surface of the carrier board 400 in a flip-chip manner, and the adhesive layer 130 is exposed on the first molding layer 150. When film assistant molding process is used for molding, the cover film is directly covered on the surface of the adhesive layer 130 or the film layer 140, and after the cover film is removed, the adhesive layer 130 or the film layer 140 is exposed.

The first molding layer 150 with a predetermined height can be directly formed by the film assistant molding process, without the need to first form a thicker pre-molding layer and then thin it to form the first molding layer 150, which avoids warping caused by excessive thickness of the pre-molding layer during manufacturing process, thereby avoiding warping affecting the process operation; moreover, directly forming the first molding layer 150 facilitates reduction of the heights of other components, e.g., it reduces the heights of the metal pillars 160, which can shorten the spacing and critical dimensions of the metal pillars 160, thus forming a higher connection density, which is conducive to the miniaturization of the product. Specifically, the spacing and critical dimensions of the metal pillars 160 are related to the heights of the metal pillars 160, the higher the heights of metal pillars 160 are, the larger the spacing and critical dimensions of metal pillars 160 are; in the formation method provided by the embodiments of the present disclosure, since there is no need to first form a thicker pre-molding layer and then thin it to form the first molding layer 150, so that when metal pillars 160 are arranged on the surface of the carrier board 400, it is not necessary to form metal pillars 160 that are of the same height as the pre-molding layer, instead, only metal pillars 160 that are of the same height as the first molding layer 150 need to be formed, which reduces the heights of the metal pillars 160, which can shorten the spacing and critical dimensions of the metal pillars 160, and thus forming a higher connection density, which is conducive to the miniaturization of the product.

In some embodiments, after the first molding layer 150 is formed, the surface of the first molding layer 150 facing away from the carrier board 400 is flush with the surface of the bridge chip component 100 facing away from the carrier board 400. Specifically, in the present embodiment, the bridge chip component 100 is arranged on the top surface of the carrier board 400 in a face-up chip manner, so that, as shown in FIG. 12, the surface of the first molding layer 150 facing away from the carrier board 400 is flush with the top surface of the film layer 140; furthermore, in this embodiment, the surfaces of the metal pillars 160 facing away from the carrier board 400 are flush with the surface of the first molding layer 150 facing away from the carrier board 400. In another embodiment, the bridge chip component 100 is arranged on the top surface of the carrier board 400 in a flip-chip manner, so that the first molding layer 150 facing away from the carrier board 400 is flush with the bottom surface of the adhesive layer 130.

In other embodiments, after the first molding layer 150 is formed, the surface of the first molding layer 150 facing away from the carrier board 400 is lower than the surface of the bridge chip component 100 facing away from the carrier board 400. Specifically, in one embodiment, the bridge chip component 100 is arranged on the top surface of the carrier board 400 in a face-up chip manner, so that the surface of the first molding layer 150 facing away from the carrier board 400 is lower than the top surface of the film layer 140. In another embodiment, the bridge chip component 100 is arranged on the top surface of the carrier board 400 in a flip-chip manner, so that the surface of the first molding layer 150 facing away from the carrier board 400 is lower than the bottom surface of the adhesive layer 130.

Referring to FIGS. 1 and 13, at step S13, the exposed adhesive layer 130 or the film layer 140 is removed. In the present embodiment, the bridge chip component 100 is arranged on the top surface of the carrier board 400 in a face-up chip manner, so that the film layer 140 is removed in this step; in another embodiment, the bridge chip component 100 is arranged on the top surface of the carrier board 400 in a flip-chip manner, so that the adhesive layer 130 is removed in this step.

In this step, methods such as UV irradiation, wet etching, dry etching, and etc., and the method of high adhesiveness material film layer adhesion may be used to remove the exposed adhesive layer 130 or the film layer 140. After the adhesive layer 130 or the film layer 140 is removed, the top surface of the internal redistribution layer 114 is lower than the top surface of the first molding layer 150, forming a groove.

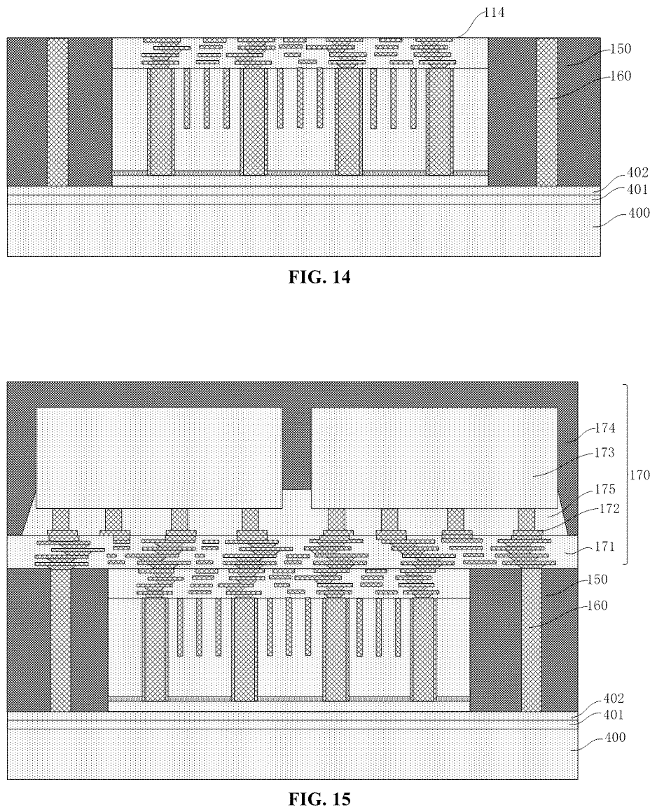

Referring to FIGS. 1 and 14, at step S14, a part of the first molding layer 150 is removed, such that the surface of the first molding layer 150 facing away from the carrier board 400 is flush with the surface of the bridge chip component 100 facing away from the carrier board 400. In the present embodiment, the bridge chip component 100 is arranged on the top surface of the carrier board 400 in a face-up chip manner, so that after a part of the first molding layer is removed, the surface of the first molding layer 150 facing away from the carrier board 400 is flush with the top surface of the internal redistribution layer 114; in another embodiment, the bridge chip component 100 is arranged on the top surface of the carrier board 400 in a flip-chip manner, so that after a part of the first molding layer 150 is removed, the surface of the first molding layer 150 facing away from the carrier board 400 is flush with the bottom surface of the protective layer 120. In some embodiments, the surface of the first molding layer 150 facing away from the carrier board 400 being flush with the surface of the bridge chip component 100 facing away from carrier board 400 includes the surface of the first molding layer 150 facing away from carrier board 400 and the surface of the bridge chip component 100 facing away from carrier board 400 are in the same plane, or the surface of the first molding layer 150 facing away from the carrier board 400 is slightly higher than the the surface of the bridge chip component 100 facing away from the carrier board 400 by predetermined distance, and the predetermined distance is 2 to 5 micrometers.

In some embodiments, a grinding and planarization process is used to remove a part of the first molding layer 150. The metal pillars 160 are further arranged in the first molding layer 150, so that in the step of removing a part of the first molding layer 150 using the grinding and planarization process, the metal pillars 160 are etched so that the surfaces of the metal pillars 160 facing away from the carrier board 400 are flush with the surface of the first molding layer 150 facing away from the surface of the carrier board 400.

Referring to FIGS. 1 and 15, at step S15, a chip package component 170 is formed on the surface of the first molding layer 150 facing away from the carrier board 400 and on the surface of the bridge chip component 100 facing away from the carrier board 400, and the bridge chip component 100 is electrically connected with the chip package component 170. In the present embodiment, the bridge chip component 100 is arranged on the top surface of the carrier board 400 in a face-up chip manner, so that the chip package component 170 is electrically connected with the internal redistribution layer 114; in another embodiment, the bridge chip component 100 is arranged on the top surface of the carrier board 400 in a flip-chip manner, so that the chip package component 170 is electrically connected with the bottom surfaces of the through-silicon-vias 112.

In one embodiment, the chip package component 170 includes a top redistribution layer 171, top solder pads 172, and a top device 173, the step of forming the chip package component 170 on the surface of the first molding layer 150 facing away from the carrier board 400 and the surface of the bridge chip component 100 facing away from the carrier board 400 includes:

The top redistribution layer 171 is formed on the surface of the first molding layer 150 facing away from the carrier board 400 and the surface of the bridge chip component 100 facing away from the carrier board 400, the top redistribution layer 171 includes a dielectric layer and conductive lines located within the dielectric layer, and the conductive lines are electrically connected with the bridge chip component 100, wherein the conductive lines are formed through an electroplating process. In one embodiment, the top redistribution layer 171 may be formed through a photolithography process and an electroplating process, for example, the top redistribution layer 171 is formed by layering and stacking through processes such as resist coating, exposure, development, electroplating, and resist stripping.

Top solder pads 172 are formed on the top surface of the top redistribution layer 171, and the top solder pads 172 are electrically connected with the top redistribution layer 171.

A top device 173 is arranged on the top redistribution layer 171, and the top device 173 is welded with the top solder pads 172. In some embodiments, the top device 173 is flip-chip mounted on the top redistribution layer 171. The top device 173 is welded with the top solder pads 172 through conductive bumps.

Molding is performed to form a second molding layer 174, the second molding layer 174 covers the top device 173. In some embodiments, before molding the top device 173, it further includes forming a filler layer 175 by filling the space between the bottom of the top device 173 and the top redistribution layer 171, and the second molding layer 174 also covers the filler layer 175.

Referring to FIGS. 1 and 16, at step S16, the carrier board 400 and the adhesive layer 130 or the film layer 140 of the bridge chip component 100 are removed, and a part of the first molding layer 150 is removed, such that the surface of the first molding layer 150 facing away from the chip package component 170 is flush with the surface of the bridge chip component 100 facing away from the chip package component 170. In the present embodiment, the bridge chip component 100 is arranged on the top surface of the carrier board 400 in a face-up chip manner, so that in this step, the carrier board 400 and the adhesive layer 130 of the bridge chip component 100 are removed, and the surface of the first molding layer 150 facing away from the chip package component 170 is flush with the bottom surface of the protective layer 120 of the bridge chip component 100, the bottom surface of the first molding layer 150, the bottom surfaces of the metal pillars 160, and the bottom surface of the protective layer 120, as well as the bottom surfaces of the through-silicon-vias 112 are exposed; in another embodiment, the bridge chip component 100 is arranged on the top surface of the carrier board 400 in a flip-chip manner, so that in this step, the carrier board 400 and the film layer 140 of the bridge chip component 100 are removed, and the surface of the first molding layer 150 facing away from the chip package component 170 is flush with the bottom surface of the film layer 140 of the bridge chip component 100, the top surface of the first molding layer 150, the top surfaces of the metal pillars 160, and the top surface of the internal redistribution layer 114 are exposed.

In this step, an appropriate debonding process is selected according to the characteristics of the temporary bonding adhesive, such as laser debonding or thermal debonding, and etc., to remove the carrier board 400. After the carrier board 400 is removed, the temporary bonding layer 401 is also removed, and the buffer metal layer 402 is removed. In this step, an appropriate process is selected according to the material properties and molecular system of the adhesive layer 130 or the film layer 140 to remove the adhesive layer 130 or the film layer 140.

In some embodiments, a grinding and planarization process is used to remove a part of the first molding layer 150. In the step of removing the adhesive layer 130 or the film layer 140, if a dry etching process is used, it will cause the bottom surface of the first molding layer 150 to be too rough, so that when using the grinding and planarization process to remove a part of the first molding layer 150, the bottom surface of the first molding layer 150 may be polished to form a surface with the required roughness. In one embodiment, in the step of using the grinding and planarization process to remove a part of the first molding layer 150, the metal pillars 160 is etched, such that the surfaces of the metal pillars 160 facing away from the carrier board 400 are flush with the surface of the first molding layer 150 facing away from the carrier board 400.

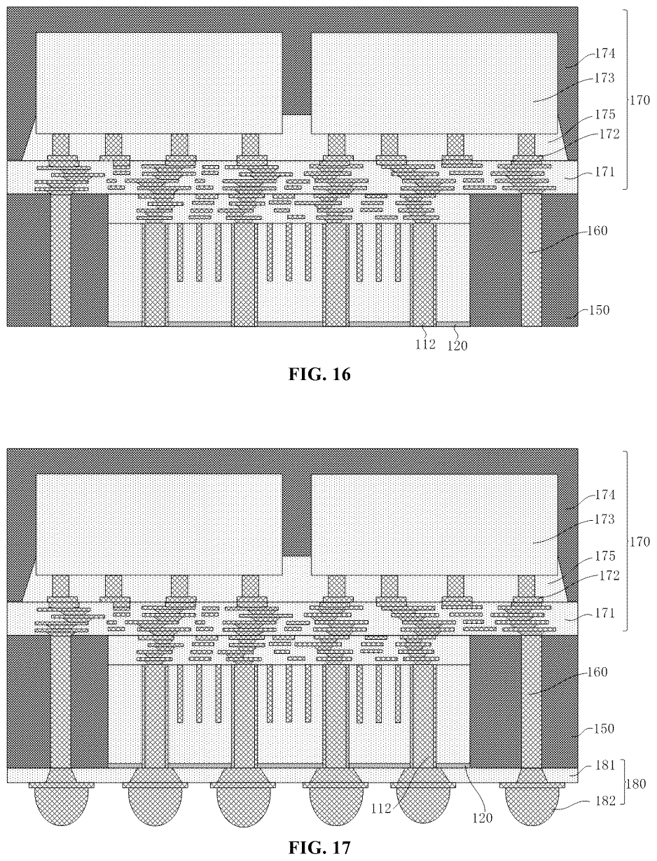

Referring to FIGS. 1 and 17, at step S17, a bottom interconnection structure 180 is formed on the surface of the first molding layer 150 facing away from the chip package component 170 and the surface of the bridge chip component 100 facing away from the chip package component 170. In the present embodiment, the bridge chip component 100 is arranged on the top surface of the carrier board 400 in a face-up chip manner, so that after this step, the bottom interconnection structure 180 is arranged on the bottom surface of the protective layer 120 and electrically connected with the through-silicon-vias 112; in another embodiment, the bridge chip component 100 is arranged on the top surface of the carrier board 400 in a flip-chip manner, so that after this step, the bottom interconnect is arranged on the top surface of the internal redistribution layer 114 and electrically connected with the internal redistribution layer 114.

In some embodiments, the step of forming the bottom interconnection structure 180 on the surface of the first molding layer 150 facing away from the chip package component 170 and the surface of the bridge chip component 100 facing away from the chip package component 170 further includes:

A dielectric layer is formed on the surface of the first molding layer 150 facing away from the chip package component 170 and the surface of the bridge chip component 100 facing away from the chip package component 170. In the present embodiment, the bridge chip component 100 is arranged on the top surface of the carrier board 400 in a face-up chip manner, so that in this step, the dielectric layer is formed on the surface of the first molding layer 150 facing away from the chip package component 170, the bottom surface of the protective layer 120 of the bridge chip component 100, and the bottom surfaces of the through-silicon-vias 112; in another embodiment, the dielectric layer is arranged on the top surface of the carrier board 400 in a flip-chip manner, so that in this step, the dielectric layer is formed on the surface of the first molding layer 150 facing away from the chip package component 170 and the top surface of the internal redistribution layer 114 of the bridge chip component 100.

Formed on the dielectric layer are through-vias which expose the bottom surfaces of the through-silicon-vias 112 or the solder pads of the internal redistribution layer 114. In the present embodiment, the bridge chip component 100 is arranged on the top surface of the carrier board 400 in a face-up chip manner, so that after this step, the through-vias expose the bottom surfaces of the through-silicon-vias 112 and the bottom surfaces of the metal pillars 160; in another embodiment, the bridge chip component 100 is arranged on the top surface of the carrier board 400 in a flip-chip manner, so that after this step, the through-vias expose the solder pads of the internal redistribution layer 114 and the top surfaces of the metal pillars 160.

Electroplating lines are formed within the through-vias by sputtering and/or electroplating, and the electroplating lines are in contact connection with the through-silicon-vias 112 or the solder pads of the internal redistribution layer 114, and the dielectric layer and the electroplating lines together serve as the bottom redistribution layer 181. In the present embodiment, the bridge chip component 100 is arranged on the top surface of the carrier board 400 in a face-up chip manner, so that after this step, the electroplating lines are in contact connection with the through-silicon-vias 112 and the metal pillars 160; in another embodiment, the bridge chip component 100 is arranged on the top surface of the carrier board 400 in a flip-chip manner, so that after this step, the electroplating lines are in contact connection with the solder pads of the internal redistribution layer. In this step, sputtering and electroplating are used to form the electroplating lines, without the need for tin (Sn) welding, which eliminates the aging issues of tin welding during process processing, and there are no issues of voids and cracks at the welding points, which improves the reliability of the package structure; moreover, efficiency and cost can be balanced through the combination of sputtering and electroplating.

A conductive connection structure 182 is formed on the bottom surface of the bottom redistribution layer 181, and the conductive connection structure 182 and the bottom redistribution layer 181 together serve as the bottom interconnection structure 180. In some embodiments, the conductive connection structure 182 includes but is not limited to controllable collapse chip connection bumps (C4).

Optionally, after or before forming the conductive connection structure 182, the second molding layer 174 is thinned to expose the top surface of the top device 173, which facilitates device heat dissipation. Optionally, after forming the conductive connection structure 182, dicing is performed to form a plurality of independent package structures, each of the package structures may include a plurality of bridge chip components 100 and a plurality of top devices 173.

In the above embodiments, the bottom surfaces of the through-silicon-vias 112 are not arranged with bottom solder pads, but they are directly connected with the bottom interconnection structure 180 or the chip package component 170; in another embodiment, bottom solder pads are arranged on the bottom surfaces of the through-silicon-vias 112, and the through-silicon-vias 112 are connected with the bottom interconnection structure 180 or the chip package component 170 through the bottom solder pads. In one embodiment, the bottom solder pads are micro solder pads (μPads). The bottom solder pads are arranged on the bottom surfaces of the through-silicon-vias 112, such that the thickness of the first molding layer 150 covering the bridge chip component 100 can be reduced in the package structure using the bridge chip component 100, thereby reducing the warping of this part of the structure, which is more conducive to production and yield. In the present embodiment, the cross-sectional areas of the bottom solder pads are larger than the cross-sectional areas of the through-silicon-vias 112 to ensure that the through-silicon-vias 112 can fully contact the bottom solder pads, which reduces contact resistance, thus reducing the delay of electrical signals.

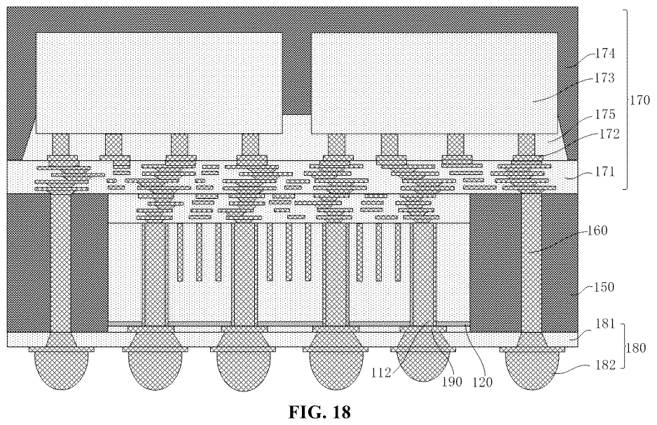

Specifically, referring to FIG. 18, it is a schematic diagram of the package structure formed by a formation method provided by another embodiment of the present disclosure, in this embodiment, after the step of thinning the passivation layer 113 and the initial through-silicon-vias 210 from the bottom surfaces of the initial through-silicon-vias 210 to form the through-silicon-vias 112 (referring to FIG. 7), it further includes: forming bottom solder pads 190, which are arranged on the bottom surfaces of the through-silicon-vias 112 and which are electrically connected with the through-silicon-vias 112. In the step of forming the adhesive layer 130 (referring to FIG. 8), the adhesive layer 130 covers the surfaces of the bottom solder pads 190 and the bottom surface of the protective layer 120. The bottom solder pads 190 may be formed through photolithography process and electroplating process.

When the bridge chip component 100 is arranged on the top surface of the carrier board 400 in a face-up chip manner, the carrier board 400 and the adhesive layer 130 of the bridge chip component 100 are removed, and a part of the first molding layer 150 is removed; after the step of making the surface of the first molding layer 150 facing away from the chip package component 170 flush with the surface of the bridge chip component 100 facing away from the chip package component 170, the bottom solder pads 190 are exposed, and the surface of the first molding layer 150 facing away from the chip package component 170 is flush with the bottom surfaces of the bottom solder pads 190; after the step of forming a bottom interconnection structure 180 on the surface of the first molding layer 150 facing away from the chip package component 170 and on the surface of the bridge chip component 100 facing away from the chip package component 170, the bottom interconnection structure 180 is connected with the bottom solder pads 190, i.e., the through-silicon-vias 112 are electrically connected with the bottom interconnection structure 180 through the bottom solder pads 190.

When the bridge chip component 100 is arranged on the top surface of the carrier board 400 in a flip-chip manner, after the step of removing the exposed adhesive layer 130 or the film layer 140, the bottom solder pads 190 are exposed; after the step of removing a part of the first molding layer 150 such that the surface of the first molding layer 150 facing away from the carrier board 400 is flush with the surface of the bridge chip component 100 facing away from the carrier board 400, the surface of the first molding layer 150 facing away from the carrier board 400 is flush with the bottom surfaces of the bottom solder pads 190; after the step of forming chip package component 170 on the surface of the first molding layer 150 facing away from the carrier board 400 and on the surface of the bridge chip component 100 facing away from the carrier board 400, the chip package component 170 is electrically connected with the bottom surfaces of the bottom solder pads 190.

The method for forming a package structure provided by the embodiments of the present disclosure reduces the covering thickness during molding of the bridge chip 110, and it reduces the thickness of the wiring interposer composed of the first molding layer 150 and the bridge chip component 100, thereby reducing warping issues and quality risks of each process during the overall manufacturing process. Furthermore, the through-silicon-vias 112 of the bridge chip 110 are exposed by the manner of depositing a protective layer 120 first and then thinning the through-silicon-vias 112, which may avoid the migration and diffusion of metal ions (e.g., copper ions) generated by thinning the through-silicon-vias 112 into the base body 111, thereby avoiding the reliability failure problems caused by the migration and diffusion of metal ions in the package structure. Meanwhile, the first molding layer 150 is directly formed using the film assistant molding (FAM) process, which avoids warping caused by excessive thickness of pre-molding layers during manufacturing process, thereby avoiding warping affecting the process operation; moreover, directly forming the first molding layer 150 facilitates reduction of the heights of other components (e.g., the heights of metal pillars 160), which can shorten their spacing and critical dimensions, and thus forming a higher connection density, which is conducive to the miniaturization of the product. The bridge chip 110 is directly connected with the chip package component 170 or bottom interconnection structure 180 through the internal redistribution layer 114 fan-out, which better meets the product application requirements of high-frequency and high-speed signals. The upper and lower surfaces of the bridge chip component 100 are of the same height as the first molding layer 150, which can further improve the interconnection density between the bridge chip 110 and the chip package component 170 on the top as well as the bottom interconnection structure 180.

Based on the same inventive concept, the embodiments of the present disclosure further provide a package structure formed using the aforementioned forming method. Referring to FIGS. 2 to 17, the package structure includes: a bridge chip component 100, the bridge chip component 100 including a bridge chip 110 and a protective layer 120; the bridge chip 110 includes a base body 111, through-silicon-vias 112 running through the base body 111, and an internal redistribution layer 114 covering the top surface of the base body 111, and the protective layer 120 is arranged on the bottom surface of the base body 111 and exposes the bottom surfaces of the through-silicon-vias 112, and the bottom surfaces of the through-silicon-vias 112 are flush with the bottom surface of the protective layer 120; a first molding layer 150, the first molding layer 150 covering the side surface of the bridge chip component 100, and the bottom surface of the first molding layer 150 is flush with the bottom surface of the protective layer 120, and the top surface of the first molding layer 150 is flush with the top surface of the internal redistribution layer 114; a chip package component 170 arranged on a surface of the first molding layer 150 and the bridge chip component 100, and the bridge chip component 100 is electrically connected with the chip package component 170; and a bottom interconnection structure 180 arranged on another surface of the first molding layer 150 and the bridge chip component 100, and the bridge chip component 100 is electrically connected with the bottom interconnection structure 180; wherein the internal redistribution layer 114 is directly electrically connected with the chip package component 170 or the bottom interconnection structure 180.

In the package structure provided by the embodiments of the present disclosure, the conductive pillars are not arranged on the top of the internal redistribution layer 114 of the bridge chip 110, which reduces the overall thickness of the bridge chip 110, thus reducing defects caused by excessive thickness of the bridge chip 110 during the manufacturing process, for example, it reduces the covering thickness during molding of the bridge chip 110, and it reduces the thickness of the wiring interposer composed of the first molding layer 150 and the bridge chip component 100, thereby reducing warping issues and quality risks of each process during the overall manufacturing process.

In the package structure provided by the embodiments of the present disclosure, the bottom surfaces of the through-silicon-vias 112 are flush with the bottom surface of the protective layer 120, wherein when manufacturing the bridge chip component 100, the protective layer 120 is first formed, then the bottom surfaces of the through-silicon-vias 112 are ground, and during the grinding process, the protective layer 120 can protect the base body 111, which may avoid the migration and diffusion of metal ions (e.g., copper ions) generated by grinding the through-silicon-vias 112 into the base body 111, thereby avoiding the reliability failure problems caused by the migration and diffusion of metal ions in the package structure.

The first molding layer 150 is directly formed by the film assistant molding (FAM) process, without the need to first form a thicker pre-molding layer and then thin it to form the first molding layer 150, which avoids warping caused by excessive thickness of pre-molding layers during manufacturing process, thereby avoiding warping affecting the process operation; moreover, directly forming the first molding layer 150 facilitates reducion of the heights of other components (e.g., the heights of metal pillars 160), which can shorten its spacing and critical dimensions, thus forming a higher connection density, which is conducive to the miniaturization of the product.

The bridge chip 110 is directly connected with the chip package component 170 or bottom interconnection structure 180 through the internal redistribution layer 114 fan-out, without the need to fan out through the internal redistribution layer 114, and then connect it with the chip package component 170 or bottom interconnection structure 180 through conductive pillars, which better meets the product application requirements of high-frequency and high-speed signals. The top surface of the first molding layer 150 is flush with the top surface of the internal redistribution layer 114, and the bottom surface of the first molding layer 150 is flush with the bottom surface of the bridge chip component 100, i.e., the upper and lower surfaces of the bridge chip component 100 are of the same height as the first molding layer 150, which can further improve the interconnection density between the bridge chip 110 and the chip package component 170 on the top (e.g., the top redistribution layer 171 in the chip package component 170) as well as the bottom interconnection structure 180 (e.g., the bottom redistribution layer 181 in the bottom interconnection structure 180).

In one embodiment, the internal redistribution layer 114 includes a dielectric layer and conductive lines located within the dielectric layer, one side of the conductive lines is electrically connected with the top surfaces of the through-silicon-vias 112, and the other side is electrically connected with the chip package component 170 or the bottom interconnection structure 180.

In one embodiment, the bridge chip 110 further includes a deep trench capacitor (DTC) 180, the deep trench capacitor is arranged within the base body 111. In some embodiments, the deep trench capacitor 180 extends from the top surface of the base body 111 toward the interior of the base body 111, and the deep trench capacitor 180 is electrically connected with the internal redistribution layer 114.

In one embodiment, a passivation layer 113 is further arranged on the side surfaces of the through-silicon-vias 112. The passivation layer 113 is used to isolate the through-silicon-vias 112 from the base body 111 to prevent metal ions in the through-silicon-vias 112 from diffusing into the base body 111.

In one embodiment, the package structure further includes metal pillars 160, and the metal pillars 160 run through the first molding layer 150, and the bottom surfaces of the metal pillars 160 are flush with the bottom surface of the first molding layer 150, and the top surfaces of the metal pillars 160 are flush with the top surface of the first molding layer 150. The package structure may include a plurality of bridge chip components 100 and a plurality of metal pillars 160, and the metal pillars 160 are distributed at the periphery of the bridge chip components 100 and between adjacent two bridge chip components 100.

In one embodiment, the chip package component 170 includes: a top redistribution layer 171 arranged on a surface of the first molding layer 150 and the bridge chip component 100, the top redistribution layer 171 includes a dielectric layer and conductive lines located within the dielectric layer, and the conductive lines are electrically connected with the bridge chip component 100; top solder pads 172 arranged on the top redistribution layer 171 and electrically connected with the top redistribution layer 171; a top device 173 arranged on the top redistribution layer 171, and the top device 173 is welded with the top solder pads 172; and a second molding layer 174 covering the top device 173. In one embodiment, the top redistribution layer 171 includes a dielectric layer and conductive lines located within the dielectric layer, and the conductive lines are in contact connection with the bridge chip component 100. The material of the dielectric layer may be a polymer material such as polystyrene butyl ester (PBO), polyimide (PI) and etc. The conductive lines are formed through an electroplating process, without the need for tin (Sn) welding, which eliminates the aging issues of tin welding during process processing, and there are no issues of voids and cracks at the welding points, which improves the reliability of the package structure. The top device 173 may be arranged on the top redistribution layer 171 in a flip-chip manner and welded with the top solder pads 172. The top device 173 may be an SOC device, and etc. In some embodiments, the package structure further includes a filler layer 175 filled between the bottom of the top device 173 and the top redistribution layer 171, and the filler layer 175 is used to protect the conductive structure of the top device 173 and the top solder pads 172. The second molding layer 174 covers the top device 173, the surface of the top redistribution layer 171, and the surface of the filler layer 175.

In one embodiment, the bottom interconnection structure 180 further includes: a bottom redistribution layer 181, the bottom redistribution layer 181 includes a dielectric layer and electroplating lines located within the dielectric layer, and the electroplating lines are in contact connection with the through-silicon-vias 112, or the bottom solder pads arranged on the bottom surfaces of the through-silicon-vias 112, or the solder pads of the internal redistribution layer 114; and a conductive connection structure 182 arranged at the bottom surface of the bottom redistribution layer 181 and electrically connected with the bottom redistribution layer 181.

In some embodiments, the bottom redistribution layer 181 includes a dielectric layer and electroplating lines located within the dielectric layer, and the electroplating lines are in contact connection with the through-silicon-vias 112 of the bridge chip 110 and the metal pillars 160. The material of the dielectric layer may be a polymer material such as polystyrene butyl ester (PBO), polyimide (PI) and etc., to further alleviate stress. In one embodiment, the electroplating lines are formed on the bottom surfaces of the through-silicon-vias 112 and the bottom surfaces of the metal pillars 160 through an electroplating process, without the need for tin (Sn) welding, which eliminates the aging issues of tin welding during process processing, and there are no issues of voids and cracks at the welding points, which improves the reliability of the package structure. The conductive connection structure 182 is arranged on the bottom surface of the bottom redistribution layer 181. In some embodiments, the conductive connection structure 182 includes but is not limited to controllable collapse chip connection bumps (C4).

In one embodiment, referring to FIG. 18, the bridge chip component 100 further includes bottom solder pads 190, and the bottom solder pads 190 are arranged on the bottom surfaces of the through-silicon-vias 112 and are electrically connected with the through-silicon-vias 112, and the bottom surface of the first molding layer 150 is flush with the bottom surfaces of the bottom solder pads 190, and the chip package component 170 or the bottom interconnection structure 180 is electrically connected with the bottom solder pads 190. In one embodiment, the bottom solder pads 190 are micro solder pads (μPads). The bottom solder pads 190 are arranged on the bottom surfaces of the through-silicon-vias 112, such that the thickness of the first molding layer 150 covering the bridge chip component 100 can be reduced in the package structure using the bridge chip component 100, thereby reducing the warping of this part of the structure, which is more conducive to production and yield. In the present embodiment, the cross-sectional areas of the bottom solder pads are larger than the cross-sectional areas of the through-silicon-vias 112 to ensure that the through-silicon-vias 112 can fully contact the bottom solder pads, which reduces contact resistance, thus reducing the delay of electrical signals.

In the package structure provided by the present disclosure, the overall thickness of the bridge chip 110 is reduced, thus reducing defects caused by excessive thickness of the bridge chip 110 during the manufacturing process. The bottom surfaces of the through-silicon-vias 112 are flush with the bottom surface of the protective layer 120, wherein when manufacturing the bridge chip component 100, the protective layer 120 is first formed, then the bottom surfaces of the through-silicon-vias 112 are ground, which may avoid the migration and diffusion of metal ions (e.g., copper ions) generated by grinding the through-silicon-vias 112 into the base body 111, thereby avoiding the reliability failure problems caused by the migration and diffusion of metal ions in the package structure. The first molding layer 150 is directly formed by the film assistant molding (FAM) process, which avoids warping caused by excessive thickness of pre-molding layers during manufacturing process, thereby avoiding warping affecting the process operation; moreover, directly forming the first molding layer 150 facilitates reduction of the heights of other components (e.g., the heights of metal pillars 160), which can shorten its spacing and critical dimensions, thus forming a higher connection density, which is conducive to the miniaturization of the product. The bridge chip 110 is directly connected with the chip package component 170 or the bottom interconnection structure 180 through the internal redistribution layer 114 fan-out, which better meets the product application requirements of high-frequency and high-speed signals. The upper and lower surfaces of the bridge chip component 100 are of the same height as the first molding layer 150, which can further improve the interconnection density between the bridge chip 110 and the chip package component 170 on the top (e.g., the top redistribution layer 171 in the chip package component 170) as well as the bottom interconnection structure 180 (e.g., the bottom redistribution layer 181 in the bottom interconnection structure 180).

It should be noted that the terms “include” and “have” and their variations referred to in the document of the present disclosure are intended to cover non-exclusive inclusions. The terms such as “first”, “second”, etc., are used to distinguish similar objects and are not necessarily used to describe a specific order or sequence, and it is appreciated that unless otherwise indicated in the context clearly, the data used in this way can be interchanged in appropriate circumstances. The term “one or more” is at least partially dependent on the context and may be used to describe features, structures, or characteristics in a singular sense or in a plural sense. The term “according to” may be understood as not necessarily intended to express a set of exclusive factors, but may alternatively, also be at least partially dependent on the context, permit the existence of other factors that may not be explicitly described. In addition, the embodiments of the present disclosure and features in the embodiments may be combined with each other without conflict. Additionally, in the above explanation, descriptions of well-known components and technologies have been omitted to avoid unnecessary confusion of the concepts of the present disclosure. In the above embodiments, each embodiment focuses on illustrating differences from other embodiments, and the same/similar parts between the embodiments can be mutually referenced.

The above is only some embodiments of the present disclosure, it should be noted that those skilled in the art may also make several improvements and refinements without departing from the principles of the present disclosure, and these improvements and refinements should also be considered as the protection scope of the present disclosure.

What is claimed is:

1. A method for forming a package structure, comprising:
forming a bridge chip component, the bridge chip component comprises: a bridge chip, a protective layer, an adhesive layer, and a film layer; the bridge chip comprises a base body, through-silicon-vias running through the base body, and an internal redistribution layer covering a top surface of the base body, and the internal redistribution layer is electrically connected with the through-silicon-vias; the protective layer is arranged on a bottom surface of the base body and exposes bottom surfaces of the through-silicon-vias, wherein the bottom surfaces of the through-silicon-vias are made flush with a bottom surface of the protective layer by depositing the protective layer first and then thinning the through-silicon-vias; the adhesive layer covers a bottom surface of the protective layer and the bottom surfaces of the through-silicon-vias; the film layer covers a top surface of the internal redistribution layer;
arranging the bridge chip component on a top surface of a carrier board in a flip-chip or a face-up chip manner;
performing molding using a film assistant molding process to form a first molding layer, which covers a side surface of the bridge chip component and a top surface of the carrier board, and the adhesive layer or the film layer is exposed on the first molding layer;
removing the exposed adhesive layer or the film layer;
removing a part of the first molding layer, such that a surface of the first molding layer facing away from the carrier board is flush with a surface of the bridge chip component facing away from the carrier board;
forming a chip package component on the surface of the first molding layer facing away from the carrier board and on the surface of the bridge chip component facing away from the carrier board, and the bridge chip component is electrically connected with the chip package component;
removing the carrier board and the adhesive layer or the film layer of the bridge chip component, and removing a part of the first molding layer, such that the surface of the first molding layer facing away from the chip package component is flush with the surface of the bridge chip component facing away from the chip package component; and
forming a bottom interconnection structure on the surface of the first molding layer facing away from the chip package component and on the surface of the bridge chip component facing away from the chip package component.

2. The method for forming a package structure according to claim 1, wherein the step of forming the bridge chip component comprises:
providing a device wafer, the device wafer comprising a bridge chip, the bridge chip comprising an initial base body, initial through-silicon-vias extending from a top surface of the initial base body toward an interior of the initial base body, and an internal redistribution layer arranged on the top surface of the initial base body, a passivation layer is covered on side surfaces and bottom surfaces of the initial through-silicon-vias, and top surfaces of the initial through-silicon-vias contact the bottom surface of the internal redistribution layer;
removing a part of the initial base body from the bottom surface of the initial base body to form the base body, an initial through-silicon-vias protrude from the bottom surface of the base body;
forming a protective layer on the bottom surface of the base body;
thinning the passivation layer and the initial through-silicon-vias from the bottom surfaces of the initial through-silicon-vias to form the through-silicon-vias, and making the bottom surfaces of the through-silicon-vias flush with the bottom surface of the protective layer, and the passivation layer is covered on the side surfaces of the through-silicon-vias;
forming an adhesive layer; and
forming a film layer.

3. The method for forming a package structure according to claim 2, wherein the step of removing a part of the initial base body from the bottom surface of the initial base body to form the base body further comprises:
removing a part of the initial base body from the bottom surface of the initial base body using a thinning and planarization process to a position at a predetermined distance from the passivation layer on the bottom surfaces of the initial through-silicon-vias; and
removing a part of the initial base body from the bottom surface of the initial base body using a dry etching process to form the base body.

4. The method for forming a package structure according to claim 2, wherein in the step of forming a protective layer on the bottom surface of the base body, the protective layer also covers the surface of the passivation layer; in the step of thinning the passivation layer and the initial through-silicon-vias from the bottom surfaces of the initial through-silicon-vias to form the through-silicon-vias, the protective layer is also thinned.

5. The method for forming a package structure according to claim 2, wherein after the step of providing a device wafer, the method further comprises: bonding a support substrate with a surface of the device wafer having the internal redistribution layer; after the step of forming an adhesive layer, the method further comprises: debonding the support substrate; after the step of forming a film layer, the method further comprises: dicing the device wafer to form the bridge chip component.

6. The method for forming a package structure according to claim 2, wherein after the step of thinning the passivation layer and the initial through-silicon-vias from the bottom surfaces of the initial through-silicon-vias to form the through-silicon-vias, the method further comprises:
forming bottom solder pads, the bottom solder pads are arranged on the bottom surfaces of the through-silicon-vias and electrically connected with the through-silicon-vias; and
in the step of forming an adhesive layer, the adhesive layer covers the surfaces of the bottom solder pads and the bottom surface of the protective layer.

7. The method for forming a package structure according to claim 1, wherein the step of arranging the bridge chip component on a top surface of a carrier board in a flip-chip or a face-up chip manner further comprises: arranging metal pillars on the top surface of the carrier board; in the step of performing molding using a film assistant molding process, the first molding layer further covers side surfaces of the metal pillars; in the step of removing a part of the first molding layer such that the surface of the first molding layer facing away from the carrier board is flush with the surface of the bridge chip component facing away from the carrier board, the metal pillars are etched to make surfaces of the metal pillars facing away from the carrier board flush with the surface of the first molding layer facing away from the carrier board; in the step of removing a part of the first molding layer such that the surface of the first molding layer facing away from the chip package component is flush with the surface of the bridge chip component facing away from the chip package component, the metal pillars are etched, such that the surfaces of the metal pillars facing away from the chip package component are flush with the surface of the first molding layer facing away from the chip package component.

8. The method for forming a package structure according to claim 1, wherein in the step of performing molding using a film assistant molding process to form the first molding layer, the surface of the first molding layer facing away from the carrier board is flush with the surface of the bridge chip component facing away from the carrier board, or the surface of the first molding layer facing away from the carrier board is lower than the surface of the bridge chip component facing away from the carrier board.

9. The method for forming a package structure according to claim 1, wherein a grinding and planarization process is used to remove a part of the first molding layer.

10. The method for forming a package structure according to claim 1, wherein the step of forming a chip package component on the surface of the first molding layer facing away from the carrier board and on the surface of the bridge chip component facing away from the carrier board comprises:
forming a top redistribution layer on the surface of the first molding layer facing away from the carrier board and on the surface of the bridge chip component facing away from the carrier board, the top redistribution layer comprises a dielectric layer and conductive lines located within the dielectric layer, and the conductive lines are electrically connected with the bridge chip component, wherein the conductive lines are formed by an electroplating process;
forming top solder pads on a top surface of the top redistribution layer, the top solder pads are electrically connected with the top redistribution layer;
arranging a top device on the top redistribution layer, the top device is welded with the top solder pads; and
molding to form a second molding layer, the second molding layer covers the top device.

11. The method for forming a package structure according to claim 6, wherein the step of forming a bottom interconnection structure on the surface of the first molding layer facing away from the chip package component and on the surface of the bridge chip component facing away from the chip package component further comprises:
forming a dielectric layer on the surface of the first molding layer facing away from the chip package component and on the surface of the bridge chip component facing away from the chip package component;
forming, on the dielectric layer, through-vias exposing bottom surfaces of the through-silicon-vias, or the bottom solder pads on the bottom surfaces of the through-silicon-vias, or the solder pads of the internal redistribution layer;
forming electroplating lines within the through-vias by sputtering and/or electroplating, the electroplating lines are in contact connection with the through-silicon-vias, or the bottom solder pads, or the solder pads of the internal redistribution layer, and the dielectric layer and the electroplating lines together serve as a bottom redistribution layer; and
forming a conductive connection structure on a bottom surface of the bottom redistribution layer, the conductive connection structure and the bottom redistribution layer together serve as the bottom interconnection structure.

12. A package structure, comprising:
a bridge chip component, the bridge chip component comprising a bridge chip and a protective layer; the bridge chip comprises a base body, through-silicon-vias running through the base body, and an internal redistribution layer covering a top surface of the base body, and the protective layer is arranged on a bottom surface of the base body and exposes the bottom surfaces of the through-silicon-vias, and the bottom surfaces of the through-silicon-vias are flush with a bottom surface of the protective layer;
a first molding layer, the first molding layer covering a side surface of the bridge chip component, and a bottom surface of the first molding layer is flush with the bottom surface of the protective layer, and a top surface of the first molding layer is flush with a top surface of the internal redistribution layer;
a chip package component arranged on a surface of the first molding layer and the bridge chip component, and the bridge chip component is electrically connected with the chip package component; and
a bottom interconnection structure arranged on another surface of the first molding layer and the bridge chip component, and the bridge chip component is electrically connected with the bottom interconnection structure,
wherein the internal redistribution layer is directly electrically connected with the chip package component or the bottom interconnection structure.

13. The package structure according to claim 12, wherein the bridge chip further comprises a deep trench capacitor, the deep trench capacitor is arranged within the base body.

14. The package structure according to claim 12, wherein a passivation layer is further arranged on side surfaces of the through-silicon-vias.

15. The package structure according to claim 12, wherein the package structure further comprises metal pillars, the metal pillars run through the first molding layer, and bottom surfaces of the metal pillars are flush with the bottom surface of the first molding layer, and top surfaces of the metal pillars are flush with the top surface of the first molding layer.

16. The package structure according to claim 12, wherein the bridge chip component further comprises bottom solder pads, the bottom solder pads are arranged on the bottom surfaces of the through-silicon-vias and are electrically connected with the through-silicon-vias, the bottom surface of the first molding layer is flush with bottom surfaces of the bottom solder pads, and the chip package component or the bottom interconnection structure is electrically connected with the bottom solder pads.

17. The package structure according to claim 12, wherein the chip package component comprises:
a top redistribution layer arranged on a surface of the first molding layer and the bridge chip component, and the top redistribution layer comprises a dielectric layer and conductive lines located within the dielectric layer, and the conductive lines are electrically connected with the bridge chip component;
top solder pads arranged on the top redistribution layer and electrically connected with the top redistribution layer;
a top device arranged on the top redistribution layer, and the top device is welded with the top solder pads; and
a second molding layer covering the top device.

18. The package structure according to claim 16, wherein the bottom interconnection structure further comprises:
a bottom redistribution layer, and the bottom redistribution layer comprises a dielectric layer and electroplating lines located within the dielectric layer, and the electroplating lines are in contact connection with the through-silicon-vias, or the bottom solder pads arranged on the bottom surfaces of the through-silicon-vias, or the solder pads of the internal redistribution layer; and
a conductive connection structure arranged on a bottom surface of the bottom redistribution layer and electrically connected with the bottom redistribution layer.
